(19) United States
(12) Patent Application Publication
(10) Pub. No.: US 2012/0056509 A1
(43) Pub. Date: Mar. 8, 2012

(54) MECHANO-SENSITIVE ACTUATOR ARRAY

(75) Inventors: Iain Alexander Anderson, Auckland (NZ); Emilio Patricio Calius, Auckland (NZ); Todd Alan Gisby, Auckland (NZ); Benjamin Marc O'Brien, Auckland (NZ); Shane Xie, Auckland (NZ)

(73) Assignee: AUCKLAND UNISERVICES LIMITED, Auckland (NZ)

(21) Appl. No.: 13/148,639

(22) PCT Filed: Feb. 1, 2010
(86) PCT No.: PCT/NZ2010/000008

§ 371 Date: Oct. 17, 2011

(30) Foreign Application Priority Data
Feb. 9, 2009 (NZ) 574809
May 15, 2009 (NZ) 577028

(51) Int. Cl. H01L 41/09

(52) U.S. Cl. 310/317

(57) ABSTRACT

An array of actuators is provided which is adapted for sequential actuation by way of mechano-sensitivity propagating actuation through the array, triggering each actuator upon deformation thereof caused by an adjacent actuator or a load in the form of a fluid or a solid object. Actuation is thus coordinated with minimal computational overhead. Also provided is an actuator suitable for use in such an array, a method of controlling an actuator, and a method of controlling an array of mechano-sensitive actuators.

### FIELD

This invention relates to the field of bending actuators, and has particular application to dielectric elastomer actuators (DEAs). More particularly, the invention relates to an array of dielectric elastomer actuators using mechano-sensitivity or self-sensing to control actuation throughout the array.

### BACKGROUND

The manipulation of an object or fluid by converting electrical energy to mechanical energy has traditionally involved imparting a force using the rotational motion of an electric motor coupled with an impeller, propeller, wheel, track, or conveyer belt, for example. In some applications, such methods are not practical or desirable due to weight, noise, and/or efficiency, among other possible reasons. In particular, at very small scales propellers/impellers are ineffective for achieving propulsion in fluid flows having a low Reynolds number where viscous forces are significant or even dominant.

In applications such as pumping, propulsion, or conveying, for example, it is possible and in some cases preferable to use an array of bending actuators to propel an object or fluid in the manner of motile cilia. Such systems have traditionally been quite rare due to their relative complexity, cost, and/or ineffectiveness. However, an array of bending actuators can be effective in such applications.

U.S. Pat. No. 5,979,892 entitled “Controlled cilia for object manipulation”, for example, discloses the use of arrays of artificial cilia attached to a substrate which can be individually controlled by electrostatic force or heating of the cilia to move an object relative to the substrate, or vice versa.

Dielectric elastomer actuators (DEAs) are well suited for use in arrays to manipulate or propel objects or fluids.

Recent advances in bending actuators, in particular the development of Dielectric Elastomer Minimum Energy Structures (DEMES), has resulted in actuators which may be particularly suited to use as artificial cilia in an array.

International Publication No. WO 2007/096477 entitled “Actuator”, for example, discloses an actuator preferably comprising a polyethylene terephthalate (PET) sheet frame bonded with a dielectric elastomer actuator. Application of an electric field upon the elastomer causes deflection of the frame.

U.S. Pat. No. 6,781,284 entitled “Electroactive polymer transducers and actuators” discloses the use of electroactive-polymers which are pre-strained to improve their mechanical response. This document discloses the use of bending beam actuators in arrays which may be adapted for a wide range of applications.

Bending actuators such as DEMES actuators are lightweight, efficient, and powerful, however the prior art does not adequately address the problem of effectively controlling and coordinating potentially large arrays of individual actuators to propel or manipulate a fluid or object relative to the array, or conversely propelling the array or substrate relative to a fluid or object.

### OBJECT OF THE INVENTION

It is therefore an object of the invention to provide an apparatus for propelling an object or fluid using an array of actuators, and/or a method for controlling an array of actuators, in particular dielectric elastomer actuators, which overcome or ameliorate one or more disadvantages of the prior art.

Alternatively, it is an object of the invention to at least to provide the public with a useful choice.

Further objects of the invention will become apparent from the following description.

### SUMMARY OF INVENTION

According to a first aspect the invention may broadly be said to consist in an array of actuators adapted for sequential actuation by way of mechano-sensitivity propagating actuation through the array.

Preferably the actuators comprise bending actuators.

Preferably each actuator directly or indirectly imparts a force upon an adjacent actuator when at substantially maximum stroke.

Preferably the stroke paths of adjacent actuators overlap.

Preferably the actuators comprise dielectric elastomer actuators.

Preferably the dielectric elastomer actuators comprise dielectric elastomer minimum energy structure (DEMES) units.

Preferably the mechano-sensitivity is achieved using self-sensing to relate the electrical characteristics of each actuator to its physical position.

Preferably each of said DEMES units comprises a pre-stretched dielectric elastomer actuator (DEA) bonded with a flexible frame.

Preferably the DEA comprises one or more dielectric elastomer membranes each provided between compliant electrodes.

Preferably the DEA comprises at least two dielectric elastomer membranes, two outer electrodes, and at least one inner electrode, wherein the outer electrodes are grounded.

Preferably the self-sensing comprises capacitive sensing in each actuator, wherein deformation of the actuator causes a change in capacitance between two or more electrodes, detection of which triggers actuation of the actuator.

Preferably the array of actuators further comprises a power supply wherein a voltage across each actuator is controlled by pulse width modulation (PWM) of a charging current and the capacitance of each actuator is calculated from the discharge profile between pulses.

Alternatively said self-sensing comprises resistive sensing, wherein deformation of an actuator causes a change in surface resistance of at least one electrode, detection of which triggers actuation of the actuator.

Preferably the DEA is bonded with an outer surface of the frame at or adjacent the periphery of the frame.

Preferably the actuators form a closed loop to produce a repeating travelling wave pattern of actuation.

According to a second aspect, the invention may broadly be said to consist in a mechano-sensitive actuator comprising manipulation means for selectively manipulating a fluid or solid object, sensing means for sensing deformation of the manipulation means and triggering means for actuating the manipulation means upon sensing deformation thereof.

Preferably the manipulation means comprises a dielectric elastomer actuator and the sensing means is adapted to sense deformation by monitoring for changes in capacitance between at least two electrodes of the dielectric elastomer actuator.

Preferably the sensing and triggering means comprises a pulse width modulated power supply adapted to actuate the manipulation means by controlling the voltage supplied thereto, and sense deformation thereof by monitoring the discharge profile of the manipulation means between pulses.

According to a third aspect the invention may broadly be said to consist in a method of controlling an actuator, the method comprising sensing deflection of the actuator using a mechano-sensitive property of the actuator, and using the sensed information to actuate the actuator.

According to a fourth aspect, the invention may broadly be said to consist in a method of controlling an array of actuators comprising independently controlling two or more adjacent mechano-sensitive actuators according to the method of the third aspect of the invention, whereby actuation of one or more actuators causes the deformation and actuation of an adjacent actuator.

Preferably each actuator in the array is actuated by movement of an immediately preceding actuator and/or a load.

Preferably the actuator array may be triggered by selectively actuating at least one actuator in the array.

Preferably, or alternatively, the actuator array may be triggered by a load imparting a force on one or more of the actuators.

Further aspects of the invention, which should be considered in all its novel aspects, will become apparent from the following description.

### DRAWING DESCRIPTION

A number of embodiments of the invention will now be described by way of example with reference to the drawings in which:

FIG. 1 shows a dielectric elastomer actuator (DEA) according to the prior art, in (a) uncompressed, and (b) compressed states;

FIG. 2 shows a dielectric elastomer minimum energy structure (DEMES) unit suitable for use in the present invention in (a) planar, (b) partially curled, and (c) equilibrium states;

FIG. 3 shows the bond between the DEA and the frame of a DEMES unit in (a) non-inverted and (b) inverted configurations;

FIG. 4 shows an example application of a biomimetic actuator array according to the present invention;

FIG. 5 shows frames suitable for use in DEMES units having (a) a single layer DEA membrane, and (b) and (c) a double-layer DEA membrane;

FIG. 6 shows a circuit diagram of a self-sensing DEMES circuit according to the present invention;

FIG. 7 illustrates an example discharge profile for a self-sensing DEMES actuator according to the present invention;

FIG. 8 is an example state diagram for controlling a DEMES actuator in a mechano-sensitive biomimetic actuator array according to the present invention;

FIG. 9 shows a simulation of two adjacent DEMES units in both the equilibrium and actuated positions;

FIG. 10 shows diagrammatically the propagation of a “wave” of actuation of ctenophore comb paddles mimicked by a biometric actuator array according to the invention;

FIG. 11 shows a preferred design for a DEMES unit for one embodiment of the invention in a linear array of actuators;

FIG. 12 shows simulated (a) profile and (b) top-down views of the DEMES unit design of FIG. 5(b), at equilibrium;

FIG. 13 shows simulated (a) profile and (b) top-down views of the alternative DEMES unit design of FIG. 5(c), at equilibrium;

FIG. 14 illustrates an asymmetric three-phase triangular array loop;

FIG. 15 illustrates an inflated array loop;

FIG. 16 is an example of a state machine diagram for controlling each actuator in the actuator array loop of any one of FIGS. 14 to 16;

FIG. 17 illustrates diagrammatically, in use, an inflated array in the form of a ball propelled by a grid of four actuators triggered in a travelling wave pattern, wherein the actuators A, D, and C are shown in various stages of actuation in FIGS. 18(a), (b) and (c); and

FIG. 18 illustrates diagrammatically a peristaltic pump according to one possible embodiment of the invention.

### DETAILED DESCRIPTION OF THE DRAWINGS

Throughout the description like reference numerals will be used to refer to like features in different embodiments. The invention consists in an actuator array which may be said to be a biomimetic actuator array (BAA) in that, according to at least one embodiment, it mimics the propelling action of the ctenophore, or ‘comb jelly’, to provide a unique method and apparatus for manipulating liquids, gases, or solid objects, as a unique alternative to traditional methods/systems.

The ctenophore is a small sea creature that propels itself through the water using longitudinal arrays or rows of comb-like paddles; bending actuators formed by thousands of motile cilia of several millimetres in length. Cilia beat back and forwards in a two stage pattern with a rigid, forward reaching power stroke, and a whip like recovery stroke, as shown in FIG. 10. This asymmetric stroke pattern is essential to produce thrust at the scale of an individual cilium (at very low Reynolds numbers). The power stroke pushes the fluid more than the recovery stroke, giving net flow.

There are significant difficulties in using an array of mechanical actuators to imitate the behaviour of ctenophore cilia, not least of which is coordinating actuation of the actuator units to achieve the desired overall behaviour. For reasons of complexity, portability and/or power consumption, it is generally desirable to achieve such coordination of the individually actuated units with the minimum computational overhead. Furthermore, the actuator units must also be designed to produce a suitable motion and force for the intended application, while maintaining reliability and generally complying with design requirements such as size, weight, power consumption, imperviousness etcetera.

Ctenophores have no brain; a balancing organ at their mouth triggers the correct row of combs to actuate so that the animal can control its orientation. Paddle coordination within a row is achieved by way of mechano-sensitivity, wherein an actuation signal or trigger is carried along or propagated by the paddles themselves; the contact of a previous paddle triggers the motion of the next in line. The advantage of this approach, which is adopted in the method of the present invention, is that the system of paddles or actuator units are coordinated with minimal computational overhead, evident in that the ctenophore has no brain. A second advantage is that the system will respond dynamically to changing load conditions as will be described herein below.

Although cilia are successfully applied by ctenophores for propulsion, an artificial array of cilia on a substrate may additionally or alternatively be used to propel objects and/or fluids relative to the substrate, or to propel the substrate relative to an object or fluid. Example applications of the BAA in pumping, object manipulation, and marine propulsion are described herein below merely as examples of the many diverse applications of the technology, which is particularly attractive for use in small scale and/or portable systems due to their relatively small size, weight, and efficiency. Accordingly, a system using the BAA may comprise one or more one-dimensional arrays or rows of actuators, or one or more two-dimensional arrays of actuators each provided on a single substrate.

### Design and Simulation

To create a biomimetic mechano-sensitive actuator array inspired by ctenophores, an array of bending actuators must be provided which are each capable of detecting an external force, such as that created by direct contact with at least one adjacent actuator or indirect contact via a load, to trigger its own actuation and thus self-organise a wave of actuation. Accordingly, mechano-sensitivity in the context of a biomimetic actuator array may be defined as the capability of a bending actuator detecting an externally-induced deformation or perturbations, enabling the actuator to detect an external force thereupon.

The bending actuator may be thought of as a manipulation means for selectively manipulating a fluid or solid object.

Dielectric elastomer minimum energy structures (DEMES) are the preferred bending actuators for the present invention, as electrical properties of each DEMES unit can be measured and related to the position of the tip of the bending actuator to detect movement and propagate actuation sequentially through the array. In some applications, several spaced “waves” of actuation may propagate through a single array at any time.

Although the invention is described herein below with respect to the preferred embodiment wherein the individual actuator units of the array comprise bending actuators, and more specifically dielectric elastomer minimum energy structures (DEMES), it should be appreciated that alternatives to DEMES and/or dielectric elastomer actuators (DEA) may be used without departing from the scope of the invention. Possible alternatives may include bimetallic strips, ionic electro-active polymers, or electrostatic controlled actuators such as that described by U.S. Pat. No. 5,979,892. However, to achieve a ciliated propulsion system similar to that of the ctenophore as in at least one embodiment of the invention, the actuator array must comprise bending actuators that can be easily fabricated at the meso-scale, can be rendered mechano-sensitive, and are ideally capable of providing lightweight propulsion in fluid, for example.

Individual DEMES bending actuators, referred to as “units” throughout the description for convenience, comprise pre-stretched Dielectric Elastomer Actuator (DEAs) adhered to a thin flexible frame.

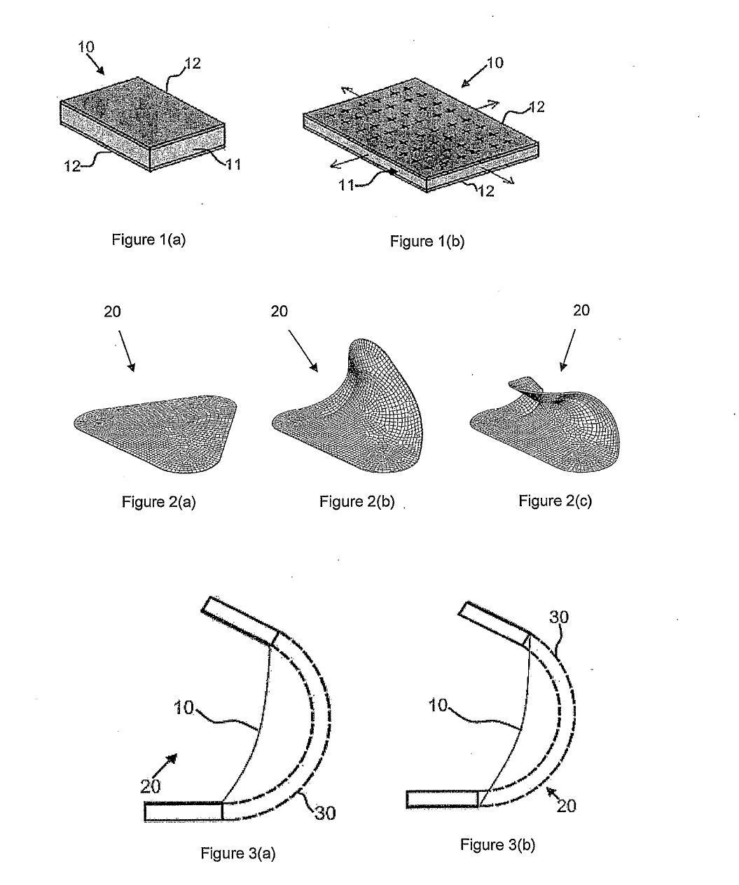

A dielectric elastomer actuator (DEA) generally referenced 10, typically comprises a dielectric elastomer membrane 11 provided between compliant electrodes 12 as shown by way of example in FIG. 1(a). The dielectric elastomer membrane 11 is compressed by electrostatic pressure when a high voltage is applied across the electrodes 12 in the manner of a capacitor, causing planar expansion of the polymer as shown in FIG. 1(b).

According to the preferred embodiment of the invention, the DEA of each DEMES actuator unit comprises two dielectric elastomer membranes 11, and three compliant electrodes 12. One of the electrodes 12 is provided between the membranes 11, with the other two electrodes being provided on opposing outer surfaces of the membranes 11. This configuration allows the outer electrodes 12 to be grounded with a charge supplied to the inner electrode 12 to actuate the DEA. Alternatively, the DEA may also comprise more than two membranes and more than three electrodes. There are several advantages in having the relatively exposed outer electrodes 12 grounded. These advantages include allowing for dense actuator arrays without fear of discharge or shorting when adjacent units touch, increasing the absolute capacitance of the system thereby improving the signal to noise ratio of the capacitive self-sensor, and reducing cross-talk between adjacent units by shielding electrostatic noise, environmental compatibility and water tolerance, for example.

DEA have garnered the moniker “artificial muscles” as they excel across a variety of actuator performance characteristics with large active strains and specific stresses, silent operation, audio bandwidths, and, significantly, the ability to operate in both sensor and generator modes.

An example of a simple DEMES unit comprising a DEA and a frame is shown diagrammatically in FIGS. 2(a)-2(c) generally referenced 20. When the stretched DEA 10 is bonded to a planar flexible frame (detail not shown) to form the DEMES unit 20, it causes the initially flat frame as shown in FIG. 2(a) to curl as shown in FIG. 2(b), until it reaches equilibrium where the strain energy in the DEA 10 equalises with the bending energy in the frame to form the complex 3D structure shown in FIG. 2(c). When the DEA 10 is actuated the energy equilibrium shifts and the frame flexes towards the planar state of FIG. 2(a). Similarly, short-circuiting the electrodes 12 causes the DEMES unit to return towards the equilibrium state of FIG. 2(c).

A large number of factors must be considered in designing the suitable DEMES units for use in a biomimetic actuator array. The DEMES units must be designed in such a way that they can be incorporated into a mechano-sensitive array with sufficient stroke and equilibrium positions for direct or indirect contact to occur between adjacent units for mechano-sensitivity to propagate actuation sequentially through the array, while deforming predictably and reliably after many cycles of actuation.

Due to their inherently non-linear and time dependent natures, manual design of DEMES can be a difficult and counter-intuitive process. For this reason, a finite element modelling approach may be used to help with design of the mechano-sensitive array. The preferred approach utilizes an Arruda-Boyce strain energy function augmented with an electrostatic energy density term to describe the DEA membranes. This is an improvement over existing methods of simulating Maxwell pressure that apply a stress in the thickness direction, as it enables the use of computationally efficient membrane elements in a state of plane strain and simplifies the membrane thickness calculations.

According to the preferred embodiment of the invention, the biomimetic actuator array comprises a row of DEMES units which may be provided on a substrate arranged in such a way that they contact the adjacent unit at nearly maximum stroke. Substrate, for the purpose of this description, means any surface upon which adjacent DEMES units or bending actuators of the array are formed or affixed.

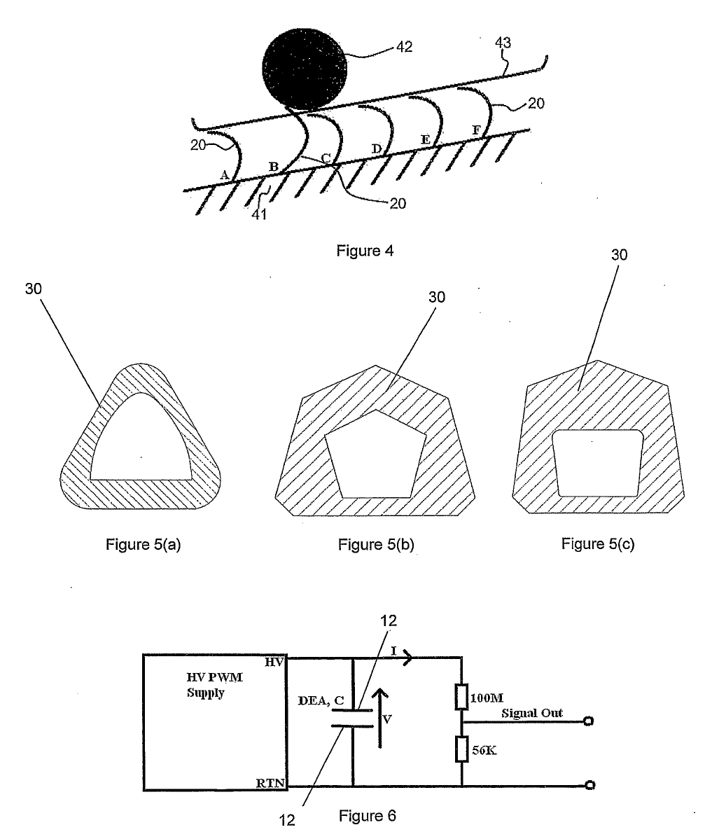

FIG. 4 illustrates diagrammatically a simple example of one possible application of a BAA according to the invention, in which the actuator array can be used to propel a cylinder or ball 42 along a pair of rails 43 provided substantially parallel with the substrate 41. The DEMES units are mechano-sensitive and will actuate upon the contact of a previous unit in the array. The ball 42 begins at or adjacent the DEMES unit 20 indicated A, which is triggered to actuate, pushing the ball 42 along the rails 43 until the tip of the DEMES unit A contacts or is substantially adjacent the adjacent DEMES unit 20 indicated B triggering actuation thereof. This process repeats, propagating actuation of consecutive DEMES units 20 until the unit indicated F is actuated and the ball reaches the end of the rails 43.

Although in the example of FIG. 4 the BAA is depicted as a single straight row of DEMES units provided on a planar substrate, the system may be adapted to follow curved rails by having a similarly shaped substrate. In other applications, the DEMES units 20 may be triggered by an external force or indirect contact which may typically arise as a result of contact with the load (such as the ball 42 in the above example), or the contact/force upon one unit 20 may additionally or alternatively be used to trigger another, possibly non-adjacent, actuation unit 20.

Due to the difficulties in designing the BAA, and in particular designing the DEMES units to produce the required force, design may be aided by modelling or simulation. In particular, finite element analysis (FEA) may be used to effectively simulate DEMES behaviour. Membrane elements are preferably used to simulate the DEA membrane and shell elements used to simulate the frame. These elements are critical as they are designed for and well suited to high aspect ratio structures. The use of continuum elements results in a poorly conditioned and unwieldy simulation with orders of magnitude greater element numbers, and more degrees of freedom per element.

Membrane elements provide an efficient method of simulating DEA membranes; however it is not possible to apply a Maxwell pressure as defined by equation 1 in the traditional manner as membrane elements exist in a state of plane strain.

P_{Maxwell}=∈ₒ∈ᵣE² (1)

To overcome this, an Arruda-Boyce strain energy function may be augmented with the electrostatic energy density of the actuator (equation 2) to simulate DEA membranes without resorting to a through thickness Maxwell pressure.

$${U}_{electrostatic} = \frac{1}{2} {ɛ}_{o} {ɛ}_{r} {E}^{2} \qquad ( 2 )$$

Visco-elasticity may be accounted for by applying a Proney series relaxation function to the whole strain energy function and pre-multiplying the electrostatic term with the inverse of the long term relaxation. This limits the simulation to quasi-static cases.

As an example of the use of FEA in designing suitable DEMES units, FIG. 9 is an overlay plot showing contact between the equilibrium state (dark) and active states (light) of two adjacent DEMES units as might be used in the example of FIG. 4. According to the design requirements of this example, the DEMES bending actuator must be able to push on the next adjacent DEMES bending actuator unit when at 75% stroke. In other words, the stroke path of adjacent DEMES units 20 must overlap. This results in two requirements; a) The DEMES must undergo sufficient stroke, and b) The DEMES must be sufficiently curled up at rest or equilibrium. This can be tested in the simulation by patterning the DEMES into an array and overlaying the equilibrium and actuated states or positions. Interaction can then be directly observed as shown in FIG. 9.

In addition, further design requirements which might apply to the DEMES units might include the minimum width of the frame being no less than 10 mm, for example, to prevent the membrane shearing off, the maximum linear strain not exceeding 1% to prevent creep, unit spacing of 20 mm, the tip must be below the rail height in the equilibrium state and must transition above the rail height to push on the ball during activation, and the capacitance change due to a tip perturbation must be greater than the noise in the capacitive self-sensor system, e.g. approximately 5 pF. Accordingly, the benefits of modelling a proposed DEMES design before fabrication are significant.

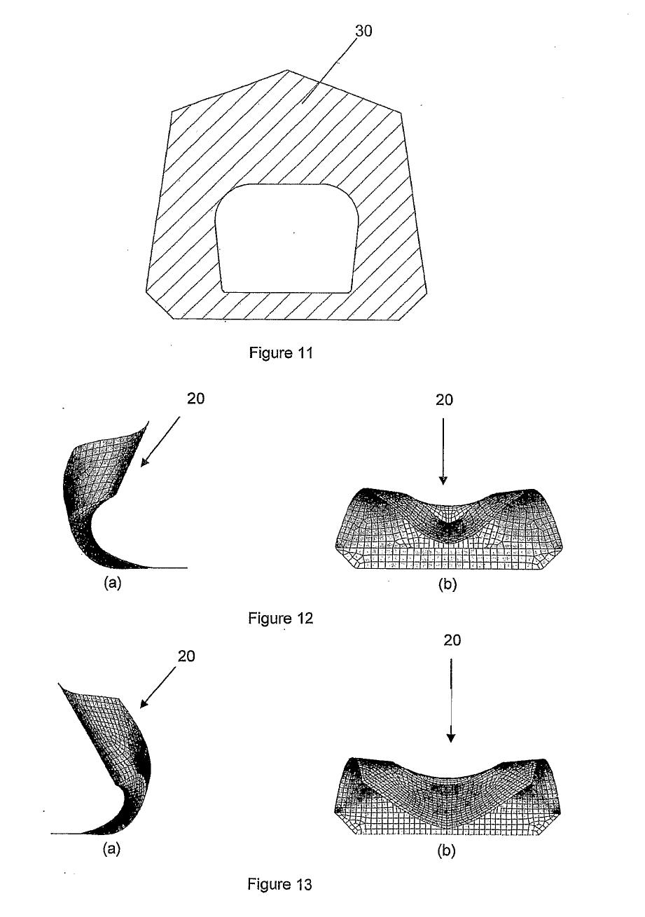

The size and shape of the frame depends largely on the application of the BAA. Three example frame designs are illustrated in FIG. 5. The frame 30 of FIG. 5(a), for example, is suitable for a single-layer DEA membrane, while the frame 30 of FIG. 5(b) is better suited for the self-sensing double-layer DEA membrane DEMES units described above. FIG. 5(c) shows an alternative frame for a double-layer DEA membrane. A further DEMES unit design, preferred for at least one application of a BAA according to the invention, is shown in FIG. 11.

FIG. 12 shows (a) profile and (b) top-down views of the simulated equilibrium position of the frame design of FIG. 5(b). FIG. 12(b) shows sharp local bending at the tip of the unit, which can lead to peeling of the membrane from the top inner point of the frame due to the angle of the membrane connection and a stress concentration caused by local bending of the frame.

FIG. 13 shows corresponding views of the simulated equilibrium position of the improved frame design of FIG. 5(c), which has approximately the same equilibrium position and stroke. From FIG. 13(b) in particular, it can be seen that this design reduces local bending near the tip of the frame and the acute angle between the frame and membrane. This smoother curve at the tip and reduced angle between the frame and membrane leads to substantially improved reliability.

### Fabrication

The frame is preferably formed from polyethylene terephthalate (PET) such as Dura-Lar™ 005 from Grafix® Plastics, although a number of other materials and processes may alternatively be used without departing from the scope of the invention, and may in some circumstances offer significant advantages.

The DEA 10 is supported on the frame 30 largely in shear. In the single/multi-layer membrane design this can lead to the membrane creeping away form the edge of the frame to some degree, potentially causing premature failure. For this reason the self sensing design preferably has a much wider frame to help prevent this failure mode.

A second challenge is that the PET material may potentially plastically deform, at strains over roughly 2% for example, depending on the temperature and type. This leads to DEMES over-curling and eventual failure. Thicker frames lead to larger strains for the same amount of curl. To overcome this problem the DEMES should be designed so that the maximum strain in the frame is less than 1%.

The ideal DEA membrane 11 for use in the DEMES unit 20 is soft to increase actuator stroke, and has a high dielectric constant and breakdown strength to produce a large compressive pressure while preventing current flowing through the membrane under compression. Increasing the dielectric constant lowers the driving voltages required to achieve useful actuation.

Suitable materials for the DEA membrane include VHB™, an acrylic elastomer available from 3M™, and silicones such as NuSil Technology LLC's CF19-2186 and Dow Corning Corporation's HS3. VHB is a highly viscous hyper-elastic material capable of high energy density for a DEA membrane. VHB is convenient to use as it comes in a neat roll and is highly adhesive, although it has a fixed thickness and formulation. Key advantages of silicones are an increased bandwidth compared to VHB, greater control over material properties such as dielectric constant and modulus, and greater control over membrane properties such as thickness and size.

According to the preferred embodiment of the invention, the electrodes 12 are created on opposing surfaces of the dielectric elastomer membrane 11 using Nyogel 756G conducting carbon grease from Nye Lubricants, Inc. The electrodes 12 may alternatively be formed by airbrushing carbon, carbon nano-tubes, ion implantation, sputter coating, or any other suitable process which would be apparent to those skilled in the art. Electrode connections may be provided with copper tape tracks, for example.

DEMES units 20 can be fabricated in-plane and form useful and efficient bending actuators or transducers for converting electrical energy to mechanical energy.

Because the DEA 10 is pre-stretched prior to bonding with the frame 30, depending on the shape of the DEMES unit it may by default be bonded to the internal or concave surface of the frame 30 at equilibrium, as shown in FIG. 3(a). The DEA-frame bond is under tension which may result in premature failure of the DEMES unit 20 due to debonding of the adhesive between the DEA 10 and the frame 30 as the DEA 10 peels from the frame 30, or debonding between the DEMES unit 20 and the substrate (not shown). To improve reliability, the DEMES unit 20 is preferably an “inverted” actuator wherein the DEA 10 is bonded with the external or convex surface of the frame 30 at or adjacent the periphery or corners of the frame 30 as shown in FIG. 3(b). The corners of the DEMES unit 20 adjacent the substrate are preferably also anchored to the substrate to prevent the corners curling up and debonding from the substrate. Alternatively, or additionally, a support bracket may be provided to hold the top surface of the DEMES down and prevent curling away from the substrate.

The DEMES units 20 of the invention may be fabricated by hand, although this is time-consuming and results in variance and non-uniformity between units. Furthermore, according to the preferred embodiment of the invention the DEMES units 20 of the BAA are fabricated at meso- (millimetre) or micro- (sub-millimetre) scales. For meso-scale fabrication, the DEMES units may be fabricated using a laser cutter such as Trotec Laser, Inc.'s Speedy 300, for example. However, in the sub-millimetre range, the use of such a laser cutter is limited due to the thermal damage zone that surrounds any cut in plastics. In this case, non-thermal Ultra Short Pulse (USP) laser systems are preferred. USP lasers create a very high intensity pulse of laser light for very short bursts (on the order of 100×10⁻¹⁵ s). The peak power output can reach the order of 1 MW. As the incident power is so high the electrons in a material absorb multiple photons and escape their parent atoms without passing any heat to the surrounding material. As the electrons escape they drag their now ionized parent atoms with them.

To prevent the actuator units 20 sticking together, a thin plastic cling wrap film or other outer layer may be applied to the contact areas of the actuators.

An array of DEMES units or actuators arranged on a substrate provides a lightweight, potentially very efficient, powerful mechanism for a BAA capable of fluid pumping, propulsion, or object conveying, among other potential applications.

### Self-Sensing

Self-sensing means that each individual actuator unit in an array or sequence of actuators is aware of their state of deformation under external or self imposed loads. In other words, deformation of an actuator by an external force can be detected, and potentially used to trigger actuation to create a self-propagating wave of actuation through the array, triggered by actuation of the first actuator unit.

Self-sensing of DEMES actuator units 20 can be achieved by sensing certain electrical parameters of the circuits, such as the capacitance or surface resistance of the electrodes, or the leakage current between electrodes 12 in the DEA. Each of these parameters changes with the geometry of the electrodes 12 and/or dielectric membrane 11 as the DEA is actuated or otherwise deformed, and therefore can be used to detect deflection or deformation caused by contact from an adjacent actuator unit 20 or an external object or force. Thus, the mechanical or physical state or position of a DEA can be inferred from monitored electrical characteristics.

Using the example of capacitive self-sensing, when the DEMES tip is pushed the membrane 11 deforms and undergoes an appreciable change in capacitance between the electrodes 12 as the membrane is compressed or expanded.

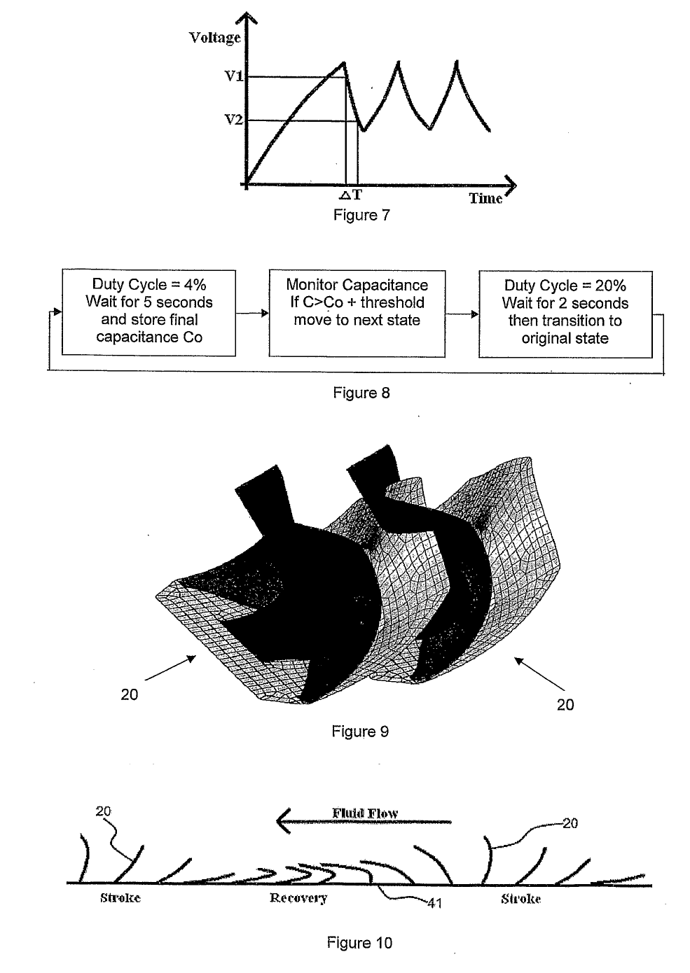

One possible, preferred, method for achieving capacitive self sensing will be described below as an example. The preferred method utilises a Pulse Width Modulation (PWM) approach, wherein the voltage on the DEA is controlled with PWM of the charging current and the capacitance is calculated from the discharge profile between pulses. An example circuit to achieve this is shown in FIG. 6. The PWM frequency should be significantly faster than the mechanical time constant of the system for large displacements, such as 200 Hz, and may be greater than 20 kHz so that the system is quiet. The mechanical system is typically slower than the PWM frequency, however the electrical system is not. The self sensor uses the discharge profile between each PWM pulse to calculate the capacitance of the DEMES as shown in FIG. 7. The discharge profile is measured using a high voltage resistor ladder and signal conditioning circuitry. The current flowing out of the DEA during the discharge part of the cycle can be approximated by equation 3, which may be modified to include a leakage current term.

$$I = \frac{\partial C}{\partial t} V + \frac{\partial V}{\partial t} C \qquad ( 3 )$$

If we assume that the capacitance of the system is undergoing negligible change while the DEMES unit 20 is in the rest or equilibrium state, then we get equation 4. The voltage is measured using a high voltage resistor ladder which allows the derivative to be known and the current is given by ohms law.

$$I = \frac{\partial V}{\partial t} C \qquad ( 4 )$$

A high-voltage DC power supply is used to provide the required voltage to the electrodes of the BAA. The PWM signals are preferably generated using high voltage optocoupler switches. The discharge and signal generation path was made with a 100 MOhm and 56 kOhm resistors in series. Low-pass filters remove high frequency noise on the signal. The entire circuit is preferably battery powered and uses separate low-dropout linear regulators for the high-voltage power pack, switches and signal conditioning circuitry.

A PWM power supply circuit as shown in FIG. 6 may thus be thought of as both the sensing means for sensing deformation of the manipulation means by measuring the discharge profile of the DEA between pulses, and the triggering means for actuating the manipulation means by controlling the voltage across the DEA.

### Control

Use of the actuator array of the present invention in applications such as propulsion requires control of the coordination of movement or actuation of the individual DEMES units 20. This usually requires the sequential actuation of adjacent units in the array, whereby the array is actuated in a “wave” pattern which propagates along the length of the array. Multiple waves may propagate simultaneously through any one array, if required.

Using a centralised controller when controlling an array can lead to computational saturation. There simply may not be enough computational power to control every element or the system as a whole if the array is large relative to the computer. Additionally, difficulties may arise from the sheer number of input/output lines required for centralised independent control of a large array of actuators. When array size becomes limited in this manner, methods of array control need to be used.

Array control approaches are reminiscent of many natural systems, in that they combine local and centralised control strategies. Cilia on ctenophores are controlled locally by their internal structure to move in the correct pattern to produce useful thrust whilst overall coordination is provided by either adjacent cilia triggering or by communication channels of smaller cilia. This is largely a form of distributed control. Cockroach legs are locally controlled via reflexes to provide rapid response to changing terrain, and are coordinated with other legs by the cockroaches' brain. This is a form of hierarchical control and allows the cockroach to traverse rough terrain at a very rapid pace. Animal muscle is controlled via a recruitment strategy to produce a varied force.

According to the preferred embodiment, however, the individual DEMES units 20 are mechano-sensitive or self-sensing. Each unit 20 in the array detects the contact of the previous adjacent unit (or some object or fluid being propelled by that unit, for example) using their self-sensing capability (e.g. a change in capacitance caused by the actuator unit being pushed by the previous actuator), and use this as a trigger for their own motion. A wave of actuation therefore propagates down the array in the same manner as a ctenophore. Each of the actuators in an array is preferably powered from a single power supply, although a plurality of power supplies may alternatively be used.

By utilising mechano-sensitivity the array achieves optimal behaviour with virtually no additional computational overhead, due to the distributed control. Consider the application of propelling a ball along some rails (which can be generalised to any conveyor application) as depicted in FIG. 4. The first DEMES unit 20 in the array pushes the ball forward until it (either the ball or the DEMES unit, depending on the set up) contacts the next DEMES unit 20 in the array. The next DEMES unit 20 detects the contact and actuates, pushing the ball forward to the next one and so on. Individual units 20 are only turned on when they are required to push the ball forward, making the system highly efficient. Thus, consecutive actuators are automatically triggered sequentially without the need for any centralised control and coordination of the independent actuators.

While sequential actuation could be achieved with simple timing of the array and no self sensing at all, an increased object mass may mean that a DEMES unit 20 takes longer to push the object to the next in line. With the timed system this means that the next in line will trigger too early and the ball will be left behind. Using the mechano-sensitive system of the present invention, the next DEMES unit 20 in line waits until the ball has moved to it. This means the system automatically adapts itself to the type of load, as well as variability between the actuators themselves, with no need for external sensors or significant computation means. The array of the present invention therefore provides a new and very lightweight mechanism for conveying objects. For applications where weight and efficiency are critical and the objects may not have regular shapes and sizes the array is particularly useful, such as a robot collecting samples of rock.

Adaptability of the mechano-sensitive array also extends to fluid propulsion and pumping. Consider a marine robot propelled with a BAA according to the present invention. The array should move at a certain speed to produce good thrust in the water. If the density of the water changes such as moving from salt to fresh water, or into an area of bubbles, the optimum speed for the array to run at will change. The mechano-sensitive array will automatically adapt to this speed, something not possible with a purely timed array. The robot could also use the array to “walk” along surfaces in a manner that is not currently possible. The array would also provide a means to increase the sensitivity of the robot to water currents and objects by turning them to a sensor mode. The array is potentially a very efficient and quiet form of propulsion providing for applications where stealth is a requirement. Like the ctenophore, a marine robot may have multiple arrays arranged in rows which may be triggered independently to control orientation.

Mechano-sensitivity may be achieved using any sensing means to detect contact between adjacent DEMES units 20, or from an external object. For example, capacitive self-sensing detects the capacitance between electrodes of each DEMES unit 20 and relates this to its mechanical state as described above. Accordingly, DEMES units 20 must be designed to undergo detectable change in capacitance with merely a small displacement of its tip caused by contact from the preceding actuator or load; to be shielded from its environment and adjacent DEMES, allowing dense packing of the actuator and safe environmental interactions; to rest in a state that the previous adjacent array unit 20 can reach to push on and to move enough to push the next adjacent unit 20; and to settle to a known state over time and not creep to failure. Other requirements will be apparent to those skilled in the art and may depend on the application of the array. For example, an array used for marine propulsion obviously requires the DEMES units to each be fundamentally waterproof.

Alternatively, as previously mentioned the sensing means may alternatively be achieved by sensing changes in the resistance of electrodes or the leakage current between electrodes in the preferred dielectric elastomer bending actuators, or using any other sensing means capable of detecting movement of at least a portion of each actuator unit. The choice of sensing means depends largely on the application of the BAA and bending actuator used therein. Depending on the sensor means used, it may not be necessary for adjacent actuators to touch, provided only that the actuation of adjacent actuator units is triggered by the movement or proximity of the preceding actuator in the array, or a load borne by the array. For example, sequential actuation may be triggered by fluid waves or baffle created by adjacent actuators, rather than contact between them. The self-sensing capability of a DEA, i.e. the capability for the DEA to act as both a sensor and a electrical-mechanical transducer, make them particularly suited to biomimetic actuator arrays as described herein above.

According to a further aspect, the invention comprises a method of controlling an actuator array by actuating a first actuator, detecting the deformation and actuating subsequent actuators sequentially by mechano-sensitivity as described herein. The invention may also be said to consist in a method of propelling an object or fluid using an array of mechano-sensitive actuators.

### Other Embodiments

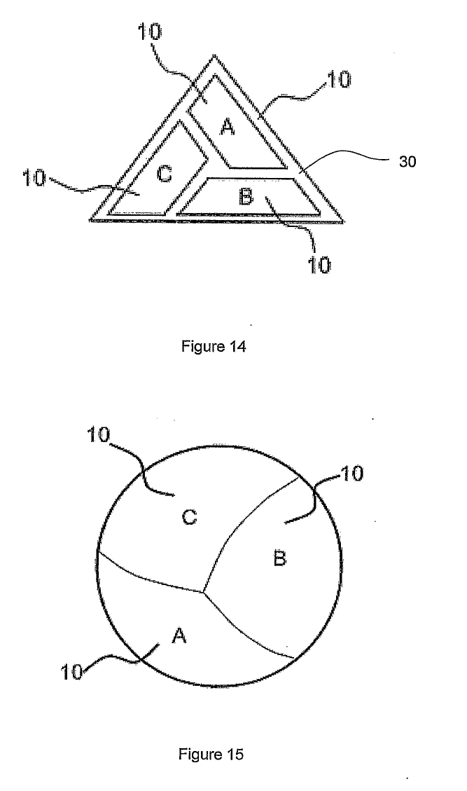

Although the invention has been described herein above with respect to a rectilinear or curved row, line, or array of bending actuators, specifically DEMES actuator units mimicking the ctenophore, according to alternative embodiments the invention may comprise a plurality of actuator units arranged in a closed loop to create a repeating wave of actuation. The closed loop may comprise, for example, an asymmetric three-phase triangular array as shown in FIG. 14, or an inflated array as shown in FIG. 15. Both the embodiments of FIGS. 14 and 15 are shown with three DEA actuators labelled A-C. Thus, the invention may also consist in an apparatus and method using bending or non-bending actuators controlled using the same principle of mechano-sensitivity as described above.

The triangular array of FIG. 14 may be formed, for example, from pre-stretched membranes of 3M™ VHB4905 adhered to a laser cut acrylic frame 30. The corners or edges of the frame 30 of the triangular array may be anchored to a mounting surface so that the expansion/contraction of each DEA 10 is substantially in-plane or planar, or alternatively the frame may be allowed to flex. The inflated array of FIG. 15 may be formed by placing the membrane over an opening and inflating it. Electrodes consisting of NyoGel 756G conductive carbon loaded grease, for example, may be painted or otherwise applied on each device in the appropriate pattern.

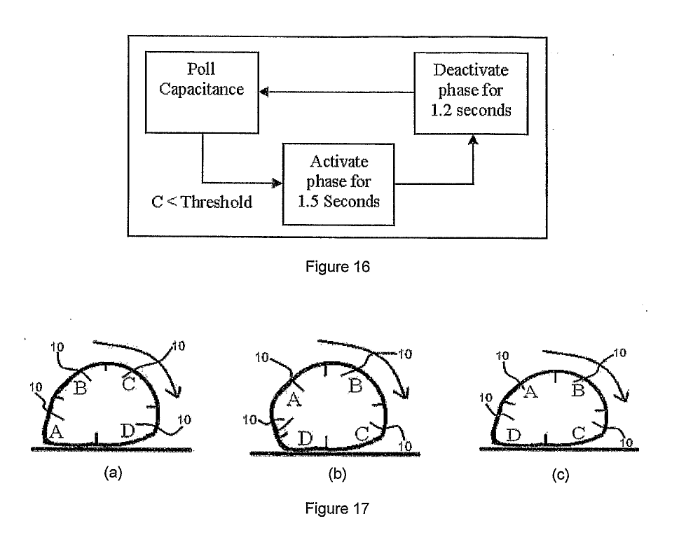

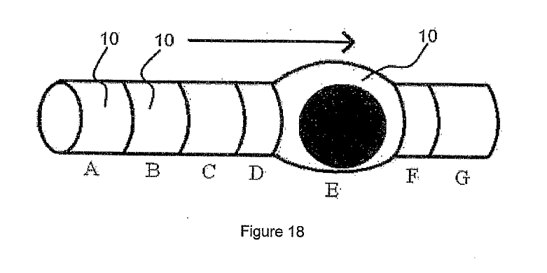

In each embodiment, actuation of the individual actuator units may be independently controlled by a simple state machine, illustrated by way of example in FIG. 16. As a DEA unit or element expands in plane the effect on a neighbouring element of the array is a contraction, and thus a reduction in area. A threshold capacitance is established for each phase or actuator unit and the state machine polls the sensor for a drop below this level. When this happens the element would undergo an actuation cycle and then return to polling the capacitance after a refractory or deactivation period to prevent the actuator being triggered by the subsequent actuator. Alternatively, or additionally, the actuator units of an actuator array loop may be designed asymmetrically such that each actuator unit is preferentially triggered by one adjacent unit (i.e. the preceding actuator unit) over the other (i.e. the subsequent actuator unit).

The particular threshold capacitance and deactivation period chosen will depend on the design of the actuator loop, and alternative control methods may be used without departing from the scope of the invention.

The triangle array loop thus forms a self-perpetuating wave of actuation propagating repeatedly from the first to the last actuator unit of the array following an initial trigger which creates a repeating rotational travelling wave, and the inflated array similarly allows a rotational travelling wave with a bulge travelling around the outside of the sphere.

The inflated array could have wide application in the field of mobile robotics, for example.

Consider an inflated ball made of DEA arranged in a grid around the outside. By deforming the ball in a rotary pattern, the ball could be made to roll where it desired, over a variety of terrain. For deployment from an airborne platform the balls could be made to bounce. With the integration of self sensing the ball could ‘rotate’ as the correct rate automatically, with a phase being triggered by the release of contact from the ground. This is shown diagrammatically in FIG. 17(a)-(c).

In another possible application, the invention may be adapted to form a robotic heart. Blood is pumped around the human body via rhythmic contraction of the heart's constituent muscles. This contraction is coordinated by the complex electro-chemo-mechanical interplay of cardiac muscle cells (myocytes). One aspect of this is mechano-sensitivity which allows the formation of feedback loops at every level of the cardiac system, from a direct influence on the cell physiology, to intercellular coupling, and to coordinating the whole organ response to changing load conditions. 3D printing techniques may potentially be used to create a real robotic heart formed by a three dimensional network of mechano-sensitive DEA for use as a flexible pump. The beating motion of the pump would be coordinated by waves of mechano-sensitive actuation running endlessly around it and would adapt to changing load conditions or deformation in the same way as a real heart. All this would be achieved with very low central computational overhead especially when considering the control challenge of coordinating the firing of sections of an entirely soft, deformable pump.

In yet another potential application of the invention, the invention may be adapted to form a peristaltic pump. Peristalsis propels objects down a flexible pipe via a wave of actuation, or a travelling pinch, as shown in FIG. 19. The human body utilises peristalsis such as in the oesophagus during swallowing, and the intestines and stomach for the passage of food and waste. DEA are well suited to this application as they are lightweight, strong, soft, flexible, potentially efficient, and suited to a wide range of environmental conditions. Control of peristalsis in the body is involuntary and in part achieved by mechano-sensitivity. That is, the distension of one area in response to a lump of material or the adjacent contraction of the structure can trigger the area to actuate. Those skilled in the art will appreciate that rendering an array of DEA actuators self-sensing further enhances the suitability for peristaltic pumps.

From the foregoing it will be seen that an actuator, an actuator array, a method of controlling an actuator, and a method of controlling an actuator array are provided which offer a number of advantages over the devices and/or methods according to the prior art. Most significantly, an actuator array according to the preferred embodiments offers an apparatus for imparting a propelling force which is lightweight, highly efficient, powerful, automatically adaptive, small, and requires minimal centralised control. Possible applications include, but are not limited to, marine propulsion, conveying objects, pumping fluids, locomotion, controlling airflow across a surface, medical devices, and many other applications where travelling waves of actuation are advantageous. The control method of the present invention provides a remarkably simple and adaptive method for controlling potentially large arrays of actuators.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Although this invention has been described by way of example and with reference to possible embodiments thereof, it is to be understood that modifications or improvements may be made thereto without departing from the scope of the invention. Furthermore, where reference has been made to specific components or integers of the invention having known equivalents, then such equivalents are herein incorporated as if individually set forth.

Any discussion of the prior art throughout the specification should in no way be considered as an admission that such prior art is widely known or forms part of common general knowledge in the field.

1. An array of actuators adapted for sequential actuation by way of mechano-sensitivity propagating actuation through the array.

2. The array of claim 1 wherein the actuators comprise bending actuators.

3. The array of claim 2 wherein each bending actuator directly or indirectly imparts a force upon an adjacent actuator when at substantially maximum stroke.

4. The array of claim 2 wherein stroke paths of adjacent bending actuators overlap.

5. The array of claim 1 wherein the mechano-sensitivity is achieved using self-sensing to relate the electrical characteristics of each actuator to its physical position.

6. The array of claim 1 wherein the actuators comprise dielectric elastomer actuators (DEAs).

7. The array of claim 6 wherein each DEA comprises at least two dielectric elastomer membranes, two outer electrodes, and at least one inner electrode, wherein the outer electrodes are grounded.

8. The array of claim 1 wherein the actuators comprise dielectric elastomer minimum energy structure (DEMES) units.

9. The array of claim 5 wherein the self-sensing is achieved by capacitive sensing in each actuator, wherein a force imparted upon an actuator causes a change in capacitance between two or more electrodes of the actuator, detection of which triggers actuation of the actuator.

10. The array of claim 5 wherein the array of actuators further comprises a power supply wherein a voltage across each actuator is controlled by pulse width modulation (PWM) of a charging current and the capacitance of each actuator is calculated from the discharge profile between pulses.

11. The array of claim 5 wherein self-sensing is achieved using resistive sensing, wherein a force imparted upon an actuator causes a change in surface resistance of at least one electrode of the actuator, detection of which triggers actuation of the actuator.

12. The array of claim 7 wherein the DEMES unit comprises a dielectric elastomer actuator bonded with an outer surface of a frame at or adjacent the periphery of the frame.

13. The array of claim 1 wherein the actuators form a closed loop to produce a repeating traveling wave pattern of actuation.

14. A mechano-sensitive actuator adapted for use in an array of actuators comprising:
a bending actuator for selectively manipulating a fluid or solid object;
a sensor for sensing deformation of the bending actuator; and
a trigger for actuating the bending actuator upon sensing deformation thereof, whereby the actuator is adapted to propagate actuation through the array by way of mechano-sensitivity.

15. The actuator of claim 14, wherein the bending actuator comprises a dielectric elastomer actuator and the sensor is adapted to sense deformation by monitoring changes in capacitance between at least two electrodes of the dielectric elastomer actuator.

16. The actuator of claim 14, wherein the sensor and trigger together comprise a pulse width modulated power supply adapted to actuate the bending actuator by controlling the voltage supplied thereto, and sense deformation thereof by monitoring the discharge profile of the bending actuator between pulses.

17. (canceled)

18. A method of controlling an actuator in an array of actuators, the method comprising sensing deformation of the actuator using a self-sensing property of the actuator, and using the sensed information to actuate the actuator, thereby propagating actuation through the array by way of mechano-sensitivity.

19. The method of claim 18, wherein deformation of the actuator is sensed by monitoring for changes in one or more of a capacitance, resistance, or leakage current of the actuator.

20. A method of controlling an array of actuators, the method comprising independently controlling two or more adjacent mechano-sensitive actuators according to the method of claim 18 whereby actuation of one actuator causes deformation and actuation of an adjacent actuator.

21. The method of claim 20 wherein each actuator in the array is actuated by movement of the immediately preceding actuator and/or a load.

22. The method of claim 20 wherein the actuator array is triggered by selectively actuating at least one actuator in the array.

23-26. (canceled)
